(19) United States
(12) Patent Application Publication
(10) Pub. No.: US 2016/0356814 A1
(43) Pub. Date: Dec. 8, 2016

(54) Modular Measuring Device using Interface Members for Testing Devices Under Test

(71) Applicant: Infineon Technologies AG, Neubiberg (DE)

(72) Inventors: Michael LARISCH, Regensburg (DE); Thomas SUTTNER, Bad Abbach (DE)

(21) Appl. No.: 15/175,743

(22) Filed: Jun. 7, 2016

(30) Foreign Application Priority Data
Jun. 8, 2015 (DE) 10 2015 109 022.8

(51) Int. Cl. G01R 1/04; G01R 1/067; G01R 1/02

(52) U.S. Cl. CPC G01R 1/0408; G01R 1/025; G01R 1/06722

(57) ABSTRACT

A measuring device for accommodating and electrically contacting a device under test to be tested in cooperation with a test apparatus, the measuring device comprising a casing comprising a first interface member being electrically couplable to the test apparatus when the test apparatus is connected to a test plug of the casing, and an exchangeable connector configured to be exchangeably assembled with the casing and comprising a second interface member being electrically couplable to a device under test when located at a device under test receptacle of the connector, wherein the first interface member and the second interface member are configured for establishing an electrically conductive connection from the device under test receptacle to the test plug upon assembling the connector with the casing.

### BACKGROUND

### Technical Field

Various embodiments relate generally to a measuring device for accommodating and electrically contacting a device under test, to a test arrangement for testing a device under test, to an interface assembly for a measuring device, and to methods of use.

### Description of the Related Art

After completing manufacture of semiconductor chips or packages of such semiconductor chips, such products are usually tested concerning their function. For this purpose, a test arrangement composed of a measuring device and a test apparatus are provided in which such products are tested as devices under test (DUT).

However, the technical effort required for such tests is significant. Moreover, testing different types of DUTs is still cumbersome.

### SUMMARY

There may be a need for a system for testing a device under test with high flexibility and reasonable effort.

According to an exemplary embodiment, a measuring device (in particular a measuring head) for accommodating and electrically contacting a device under test to be tested in cooperation with a test apparatus (in particular a measuring base) is provided, wherein the measuring device comprises a casing comprising a first interface member being electrically couplable to the test apparatus when connected to a test plug of the casing, and an exchangeable connector configured to be exchangeably assembled with the casing and comprising a second interface member being electrically couplable to a device under test when the test apparatus is located at a device under test receptacle of the connector, wherein the first interface member and the second interface member are configured for establishing an electrically conductive connection from the device under test receptacle to the test plug upon assembling the connector with the casing.

According to another exemplary embodiment, a measuring device for accommodating and electrically contacting a device under test to be tested in cooperation with a test apparatus is provided, wherein the measuring device comprises a casing, and a plurality of exchangeable connectors each configured to be exchangeably assembled with the casing and each configured for being electrically couplable to a different type of a device under test. Optionally, the casing and each of the plurality of connectors are configured for establishing an electrically conductive connection from the respective device under test receptacle to the casing upon assembling a respective one of the plurality of connectors with the casing.

According to yet another exemplary embodiment, a test arrangement for testing a device under test is provided, wherein the test arrangement comprises a measuring device having the above-mentioned features for accommodating and electrically contacting a device under test to be tested, and a test apparatus with which the measuring device is assemblable or assembled (in particular on which the measuring device is mountable or mounted), being configured for supplying (or feeding or transporting) the device under test to the connector, for applying a test signal (such as an electric test signal) via the casing to the device under test, and for receiving a response signal (such as an electric response signal) to the test signal from the device under test via the casing.

According to yet another exemplary embodiment, an interface assembly for a measuring device for accommodating and electrically contacting a device under test to be tested in cooperation with a test apparatus is provided, wherein the interface assembly comprises a first interface member for a casing of the measuring device and comprising an electrically insulating first carrier structure and one or a plurality of electrically conductive first pins extending through at least a part of the first carrier structure, and a second interface member for a connector, to be assembled with the casing, of the measuring device and comprising an electrically insulating second carrier structure and one or a plurality of electrically conductive second pins extending through at least a part of the second carrier structure, wherein the first interface member and the second interface member are configured for establishing an electrically conductive connection between the one or more first pins and the one or more second pins upon assembling the connector with the casing, wherein at least one of the first interface member and the second interface member is configured to withstand application of a high current electric test signal under high temperature conditions.

According to yet another exemplary embodiment, a method of using a measuring device having the above-mentioned features, an interface assembly having the above-mentioned features, or a test arrangement having the above-mentioned features, for testing a power package as device under test is provided, in particular a power package comprising at least one power semiconductor chip (for instance having one or more Insulated Gate Bipolar Transistors, IGBT).

According to still another exemplary embodiment, a method of using a measuring device having the above-mentioned features, an interface assembly having the above-mentioned features, or a test arrangement having the above-mentioned features is provided, wherein the method involves applying a high current electric test signal, in particular with a current of at least 4 Ampere, to the device under test, and/or heating the device under test to a temperature above ambient temperature, in particular to a temperature above 100° C.

An exemplary embodiment has the advantage that a connector can be selectively assembled with or disassembled from a casing so that it is possible to flexibly exchange the connector by another connector to thereby use one and the same casing with multiple different types of connectors. This allows to reduce the effort in terms of storage space required for storing equipment for testing different types of devices under test and/or for executing different types of tests of devices under test, when using the measuring device in conjunction with a test arrangement. Furthermore, this provision of a modular test system allows to more efficiently use material resources for test systems, since it becomes dispensable to provide a completely separate measuring device for each type of DUT and for each type of test. Advantageously, a user-friendly rapid exchangeability of the connector can be realized using cooperating interface members at casing and connector which ensure a reliable and continuous electrically conductive coupling path from one or more terminals of a device under test arranged at a device under test receptacle of the connector, via one or more terminals at the device under test receptacle, via an electrically conductive connection between the device under test receptacle and the second interface member, from the second interface member directly to the first interface member, and via an electrically conductive connection between the first interface member and the test plug.

The concept of an interface assembly of two pluggable cooperating interface members at casing and connector allows for a quick and reliable establishment of an electric connection. A corresponding electrically conductive path may work robust even under harsh conditions, in particular may be reliably maintained even at high temperatures and in the presence of high current values occurring during a test. Advantageously, such an electric connection from the DUT to the test plug may be established simultaneously with the assembly of connector and casing and does not require an additional user activity or procedure. Thus, safety in operation and a high user convenience can be synergistically combined.

### Description of Further Exemplary Embodiments

In the following, further exemplary embodiments of the measuring device, the test arrangement, the interface assembly, and the methods will be explained.

In the context of the present application, the term “device under test” (DUT) may particularly denote an electronic component such as a semiconductor package which shall be tested concerning its desired functionality after manufacture. In particular, the device under test may be an electronic member configured as a power semiconductor, in particular for automotive applications. Such devices under test may require an electric test over a broad temperature range, involving high temperatures and/or involving the application of high voltage and/or high current electric test signals.

In the context of the present application, the term “high current electric test signal” may particularly denote an electric test signal having a current value of more than 1 Ampere, in particular at least 4 Ampere, more particularly at least 10 Ampere.

In the context of the present application, the term “high temperature conditions” may particularly denote the presence of a temperature, during a test, above ambient temperature, which may be obtained by heating. Such a high temperature may be a temperature above 80° C., in particular above 140° C. Such test temperature may be required for certain tests, for instance to ensure compatibility of devices under test with requirements of certain applications, such as automotive applications.

In an embodiment, the casing and the connector are configured for being assembled by attaching the connector to the casing and actuating an actuating mechanism of the casing which simultaneously establishes the electrically conductive connection between the first interface member and the second interface member. This is a very simple procedure executable even by a user having no expert skills. The internal configuration of the connector and the casing may be such that the mere actuation of the actuating mechanism by the user completes the assembly procedure between casing and connector.

In an embodiment, the actuating mechanism comprises a lever mechanism. The simple and intuitive procedure of actuating a lever by a user may be sufficient to mount the connector to the casing.

In an embodiment, the lever mechanism comprises a lever pivotable by a user, a slanted element, and a motion conversion mechanism for converting a pivoting motion of the lever into a longitudinal motion of the slanted element, wherein the connector comprises a protrusion moving along the slanted element to thereby lock the connector to the casing (by elevating the connector towards the casing) upon pivoting the lever. In such a configuration, the user only needs to pivot the lever to assemble casing and connector. This will trigger the motion conversion mechanism (for instance a coupling rod with a toothed wheel cooperating with a pinion) to transfer a rotation motion (of the rod and the toothed wheel rigidly coupled to the rod) into a longitudinal motion (of the pinion). This longitudinal motion will, in turn, move the slanted element (such as a wedge rigidly coupled with the pinion) longitudinally, thereby forcing the protrusion of the connector to move upwardly forced by and along the slanted element. This, in turn, moves the connector upwardly, thereby establishing an engagement between the cooperating interface members while simultaneously connecting connector and casing. Such a mechanism is failure robust and easy to handle for a user.

In an embodiment, the actuating mechanism is configured for establishing the electrically conductive connection between the first interface member and the second interface number by elevating the connector towards the casing upon actuation. Thus, only one procedure needs to carried out for establishing the electric connection between the cooperating interface members and the mechanical connection between casing and connector.

In an embodiment, the actuating mechanism is configured so that, in a position of the actuating mechanism after having assembled the casing and the connector, an actuation disabling element disables further actuation of the actuating mechanism unless the actuation disabling element is, in turn, disabled by a user. Such an actuation disabling element acts as a safety mechanism against undesired disassembly of connector and casing (in particular during execution of a test) by an unintentional reverse actuation of the actuating mechanism. In the assembled (preferably not in the disassembled) condition of the measuring device, the actuation disabling element may inhibit a further actuation of the actuating mechanism so that a user has to intentionally overcome or deactivate the function of the actuation disabling element before being able to disassemble connector from casing. This additionally improves the operation safety of the measuring device, since it prevents undesired disassembly during operation of the test arrangement.

In an embodiment, the connector comprises a protrusion configured for being movable by actuating the actuating mechanism to thereby assemble the connector to the casing. This protrusion, which may be for instance a ball bearing (or a plurality of ball bearings) at the connector, may be actuated by the actuating mechanism of the casing by a follower mechanism. For example, the one or more protrusions may form part of a mounting base of the connector on which the second interface member is to be mounted. Such a mounting base may extend vertically beyond a mounting plate of the connector.

In an embodiment, the measuring device comprises a plurality of first interface members and a plurality of second interface members pairwise interacting for establishing the electrically conductive connection from the receptacle to the test plug. For example, the device under test receptacle may be located in a central lower portion of the connector and may be surrounded by two or more (in particular four) first interface members located in a peripheral upper portion of the connector. This allows for an efficient use of the available space and the simultaneous application of multiple electric test (or stimulus) signals as well as the handling of multiple response signals generated in the DUT in response to the electric test signals. For instance, four first interface members may be positioned in four corners of a rectangular mounting plate of the connector. This architecture allows for a compact design while allowing to apply a large plurality of test signals to the various terminals of the device under test.

In an embodiment, the measuring device comprises at least one further exchangeable connector, wherein each of the plurality of connectors is configured to be exchangeably assembled with the casing (however, only one at a time) and each configured for being electrically couplable to a different type of a device under test. Hence, for each type of DUT to be tested, a correspondingly configured connector may be provided which can be combined with one and the same casing for executing a certain test. The casing and each of the plurality of connectors may be configured for establishing an electrically conductive connection from the device under test receptacle to the casing upon assembling a respective one of the plurality of connectors with the casing. Therefore, a construction set of a single casing and a plurality of different connectors may be provided, wherein, depending on a respective DUT, a respective one of the connectors may be selected and connected with the casing. This reduces the required resources in terms of storage capacity and material resources required for the measuring device.

In an embodiment, the measuring device further comprises at least one further casing, wherein each of the plurality of casings is configured for supporting a respective one (or more) of different types of tests of a device under test. Additionally, the measuring device may further comprise at least one further exchangeable connector. Each of the plurality of connectors may be configured for supporting a respective one (or more) of the different types of tests of a device under test, may be configured to be exchangeably assembled with a respective one of the casings, and may be configured for being electrically couplable to a device under test being subject to testing in accordance with the respective one of different types of tests supported by the respective connector and the respective casing when a device under test is located at a device under test receptacle of the respective connector. Hence, for each type of test by which a specific DUT is to be tested, a correspondingly configured casing and a correspondingly configured connector of the modular system may be combined. This allows to manage a plurality of different kinds of tests of different kinds of devices under test in an efficient way by flexibly combining matching pairs of connector(s) and casing(s).

In an embodiment, the measuring device comprises one or more electric coupling elements electrically coupling the first interface member with the test plug and electrically coupling the second interface member with the receptacle. Such an electric coupling element may involve one or more cables, in particular one cable connection electrically coupling the first interface member with the test plug and another cable connection electrically coupling the second interface member with the receptacle. Thereby, an uninterrupted electric coupling from the device under test to the test arrangement may be accomplished.

In an embodiment, the high temperature conditions relate to a temperature of at least 100° C., in particular at least 140° C. For instance, the interface assembly may be appropriate for a test temperature of up to 150° C. and may therefore meet specific requirements of high power automotive applications.

In an embodiment, the high current electric test signal relates to a test current of at least 4 Ampere, in particular at least 10 Ampere. For instance, the interface assembly may be appropriate for a test with signal currents of up to 20 Ampere and may therefore meet specific requirements of high power automotive applications.

In an embodiment, at least one of the first carrier structure and the second carrier structure comprises a fabric-based plastics or laminated fabric, in particular comprising fibers embedded in a resin matrix. Such a composition of fiber and resin may meet the above-mentioned high temperature and high current requirements.

In an embodiment, at least one of the first interface member and the second interface member is equipped with a creep current path length extension feature. In particular in the event of high voltage and/or high current test signals, it may happen under undesired circumstances that creep currents flow between terminals of the interface members which need to remain electrically isolated from one another. This may result in a failure of the interface assembly or the entire measurement device. However, when taking a specific provision (for instance in terms of geometrical adaptation and/or material selection) to increase the length of a creep current flow path between such different terminals, the risk of failure due to creep currents may be significantly reduced.

In an embodiment, the creep current path length extension feature is formed as at least one cup shaped recess in at least one main surface portion of at least one of the first carrier structure and the second carrier structure so that, when a respective one of the one or more first pins and the one or more second pins is embedded in a respective one of the first carrier structure and the second carrier structure, the respective cup shaped recess circumferentially spaces the respective carrier structure with regard to the respective pin in the respective surface portion of the respective carrier structure. In particular, each of the carrier structures of the cooperating interface members may have cup shaped recesses in which the respective pin can be located however maintaining a (for instance hollow cylindrical) gap in the exterior main surface portions of the carrier structures. This significantly increases a path length along which a creep current (to be prevented) has to flow for short-circuiting different pins.

In an embodiment, the one or more second pins comprise an elastic bearing, in particular a spring-based bearing, configured for enabling an axial balancing motion. This allows an axial equilibration motion of the pins when the interface members of the connector and the casing are connected to one another. Undesired mechanical load due to a slight positional mismatch upon connection of the interface members can therefore be reliably suppressed. Moreover, the at least one second pin may be biased against the corresponding at least one first pin due to the elastic bearing, thereby further promoting a reliable electric connection between first pin and second pin. In particular, the second pins may be configured as pogopins.

In an embodiment, the first pins in the first carrier structure comprise a floating bearing configured for enabling a radial balancing motion. Thus, also in the plane perpendicular to a plugging direction along which the interface members are connected, a certain clearance or spatial equilibration motion of the pins may be enabled. By taking this measure, the mechanical loads acting on the interface assembly can be reduced, thereby preventing damage even in the event of repeated use of the casing with multiple different connectors.

In an embodiment, the one or more second pins comprise a tapering end, for instance an arrow shaped tapering end. More particularly, the tapering end may have multiple separate contact surfaces, configured for reversibly engaging in a sleeve shaped end of a respective one of the one or more first pins. By configuring the head of the one or more second pins with a (for instance conically) tapering end, the electric contact surface may be increased, thereby improving the reliability of the electric connection between the cooperating pins. Even more preferred is the configuration of the head of the second pins with multiple separate contact surfaces (for instance shaped like a crown), preferably with edges between adjacent contact surfaces, since this further increases the surface area and ensures a very reliable electric coupling.

In an embodiment, the first interface member and the second interface member are configured to maintain spaced by a predefined distance between the first carrier structure and the second carrier structure upon assembling the connector with the casing (and upon establishing the electrically conductive connection between the at least one first pin and the at least one second pin). This spacing, which is maintained even when the casing and the connector are in a locked condition between the first and the second pins, contributes to the suppression of creep currents.

In an embodiment, the interface assembly comprises a positioning bolt configured for engaging in corresponding positioning recesses of each of the first interface member and the second interface member so that assembly of the first interface member and second interface member is only enabled in positions in which the positioning bolt extends into the positioning recesses of both interface members. Advantageously, the positioning recesses are only formed in surface portions of the interface members which are juxtaposed to one another in the locked condition between connector and casing. When both interface members are mounted correctly, the positioning bolt engages both positioning recesses and allows for a coupling between the interface members. If however one of the interface members is mounted positionally incorrectly, the positioning bolt abuts against the exterior surface of one of the interface members and disables coupling between the interface members.

The above and other objects, features and advantages will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 shows a three-dimensional view of a measuring device according to an exemplary embodiment.

FIG. 2 shows a three-dimensional view of an exchangeable connector usable for the measuring device of FIG. 1.

FIG. 3A and FIG. 3B show three-dimensional views of a casing of the measuring device of FIG. 1.

FIG. 4 shows a three-dimensional bottom view of the measuring device of FIG. 1 with the connector of FIG. 2 in a locked state of connector and casing.

FIG. 5 shows a three-dimensional bottom view of the measuring device of FIG. 1 with the connector of FIG. 2 in an unlocked state of connector and casing.

FIG. 6 to FIG. 8 show a three-dimensional view and a cross-sectional view of a respective interface assembly according to an exemplary embodiment of the invention.

FIG. 9 shows an interface assembly of two interface members in an assembled state according to an exemplary embodiment of the invention.

FIG. 10 shows the interface assembly of FIG. 9 in a non-assembled state.

FIG. 11A and FIG. 11B show illustration of a test arrangement according to an exemplary embodiment of the invention.

### DETAILED DESCRIPTION

The illustration in the drawing is schematically and not to scale.

Before exemplary embodiments will be described in more detail referring to the figures, some general considerations will be summarized based on which exemplary embodiments have been developed.

According to an exemplary embodiment, an interface assembly with cooperating interface members (which may also be denoted as interface blocks) is provided, which may be capable for operation with high-voltage (in particular up to 6 kV or more) and/or high current (in particular up to 24 Ampere or more) and/or high-temperature (in particular up to 150° C. or more). Such an interface assembly may be capable of transferring high-voltage and high current signals at high temperature in a measuring device (such as a measuring head) with exchangeable connector.

A corresponding measuring device according to an exemplary embodiment can be composed of a casing and a connector with a rapid change functionality. Thus, exchange of a connector by another connector of another type is possible (for instance allowing to provide only one casing with different connectors for supporting tests of different types of devices under test, such as DUTs of different dimensions, different number of terminals, different function, etc.). Such a construction set of one casing and multiple connectors is a compact solution which reduces the required storage capacity and the expenses of providing and composing the various measuring devices.

It is also possible to provide a modular system of multiple casings and multiple connectors which can be paired in accordance with a certain type of test to be executed under consideration of a corresponding DUT to be tested. This allows, for instance, to selectively combine casings and connectors to support a static test (and then function as a static test measuring device) or an Iso-test (and then function as an Iso-measuring device).

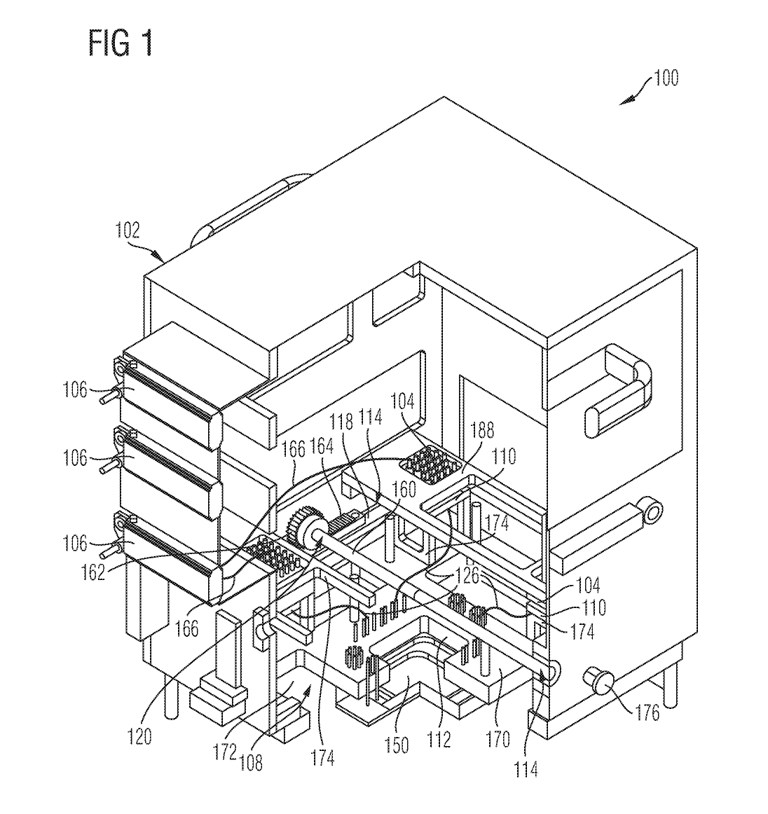

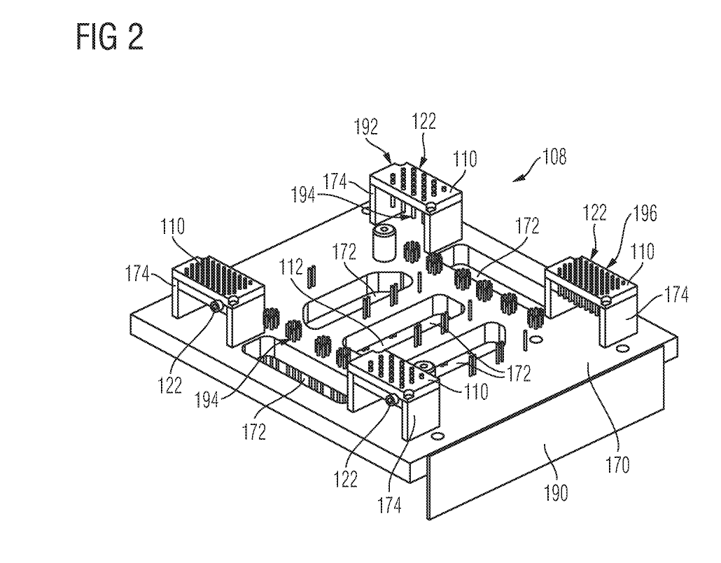

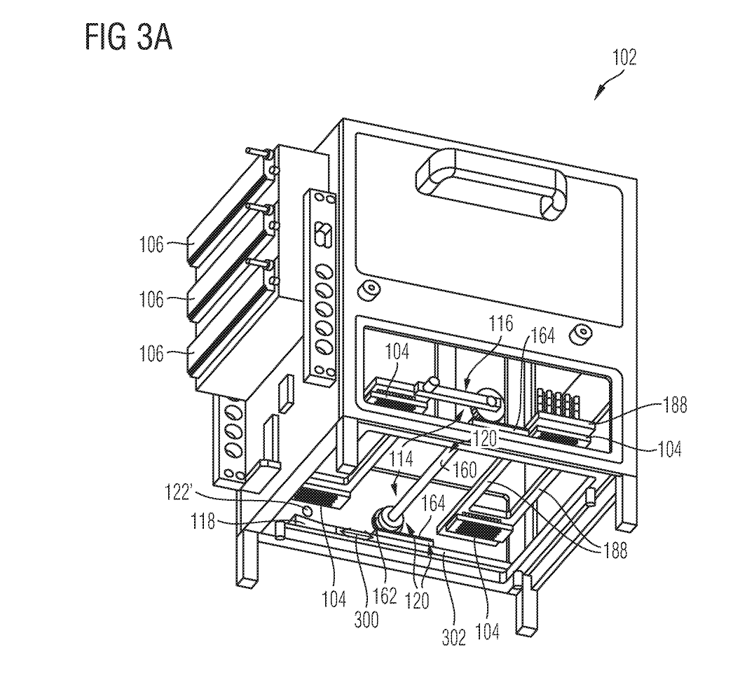

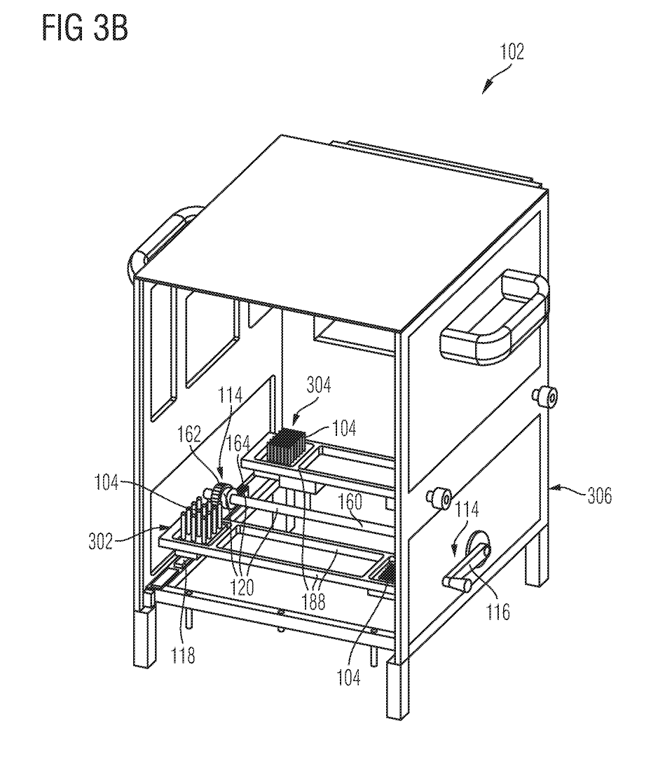

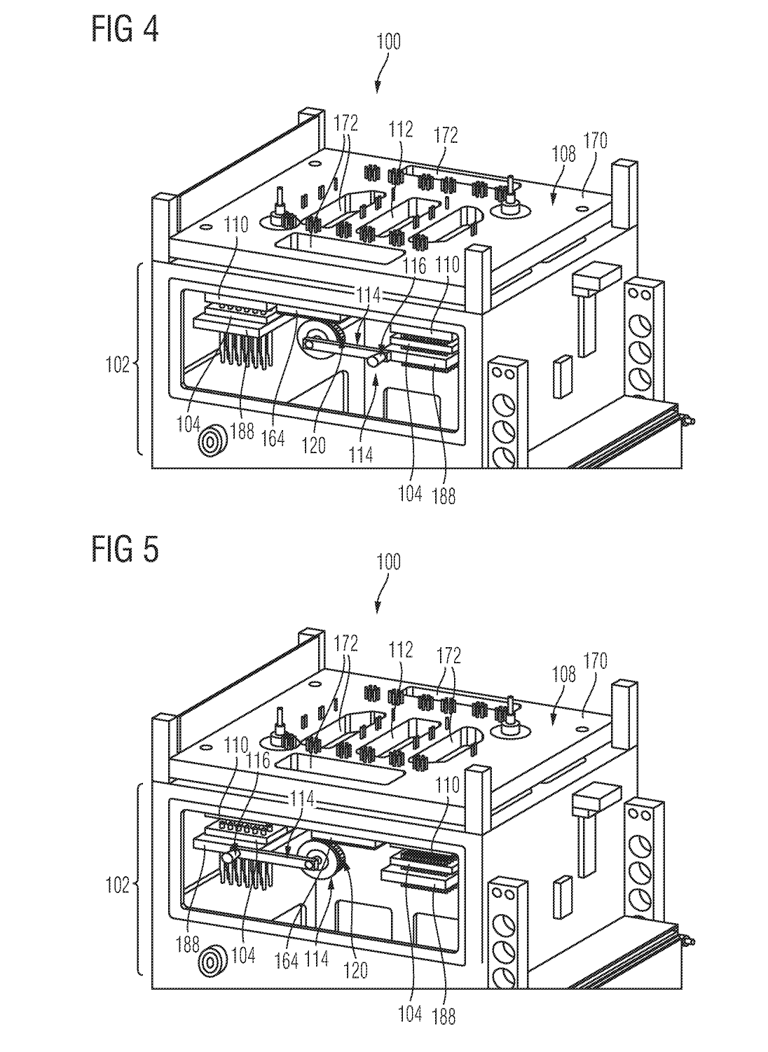

FIG. 1 shows a three-dimensional view of a measuring device 100 according to an exemplary embodiment. FIG. 2 shows a three-dimensional view of an exchangeable connector 108 which may be used for the measuring device 100 of FIG. 1. FIG. 3A and FIG. 3B show three-dimensional views of a casing 102 of the measuring device 100 of FIG. 1. FIG. 4 shows a three-dimensional bottom view of the measuring device 100 of FIG. 1 with the connector 108 of FIG. 2 in a connected state of connector 108 and casing 102. FIG. 5 shows a three-dimensional bottom view of the measuring device 100 of FIG. 1 with the connector 108 of FIG. 2 in an unconnected state of connector 108 and casing 102.

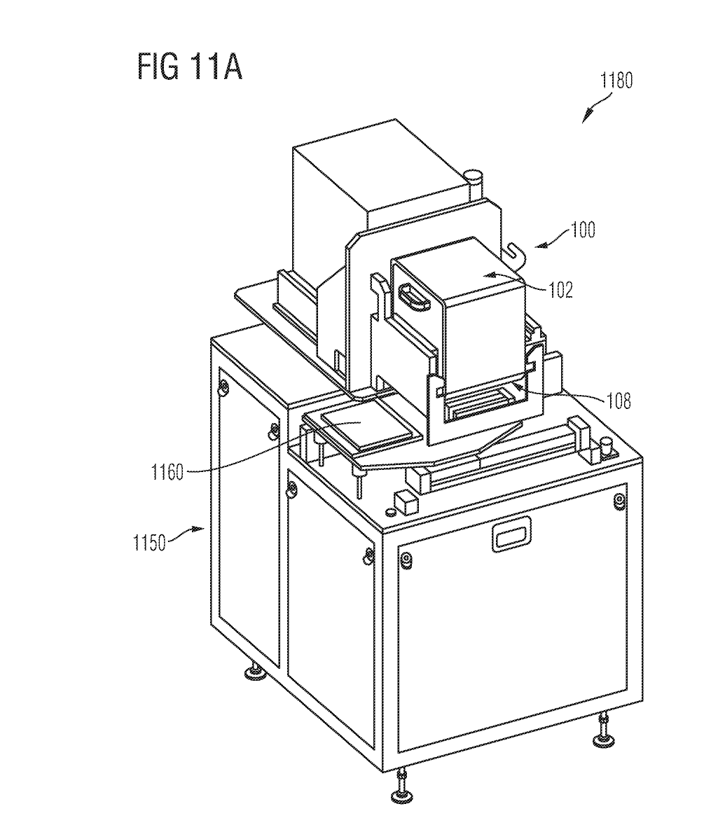

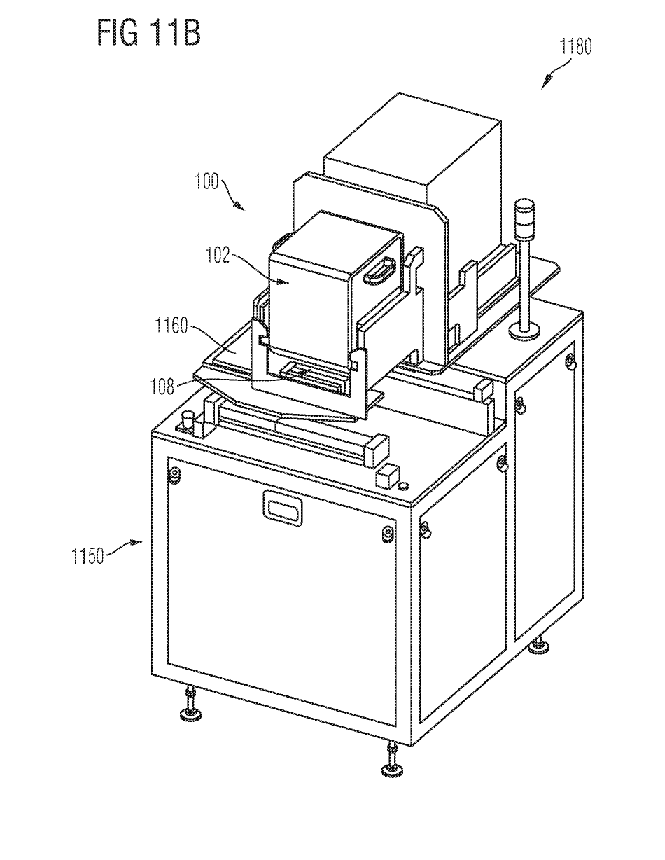

The measuring device 100 is composed of two modules, i.e. the casing 102 and the exchangeable connector 108 (which can be exchanged by another exchangeable connector 108, not shown). The measuring device 100 is configured for accommodating and electrically contacting a device under test 150 (such as a hybrid package module, for instance for automotive applications) to be tested in cooperation with a test apparatus 1150 shown in FIG. 11A and FIG. 11B which are described below in further detail. During such a test, the device under test 150 may be fed by the test apparatus 1150 to an open bottom of the measuring device 100 where one or more electric terminals of the device under test 150 may be contacted by corresponding terminals at a device under test receptacle 112 of the connector 108.

The measuring device 100 may be composed of a single casing 102 and multiple exchangeable connectors 108 having different configurations, for instance each being configured for testing a different type of devices under test 150, wherein one of the connectors 108 is mounted on the casing 102 at a time. It is also possible to combine one of multiple casings 102 with one of multiple connectors 108 to render the modular system compatible with different test schemes or protocols, for instance in accordance with different electric test signals and/or different test conditions such as temperature.

The casing 102 comprises first interface members 104 being electrically couplable to the test apparatus 1150 when the test apparatus 1150 is connected to (in the shown embodiment three) test plugs 106 of the casing 102. The first interface members 104 are accommodated in a floating way at a frame 188 of the casing 102. For certain tests (such as an Iso test), a single test plug 106 can be sufficient. For other tests however (such as a static test with high current or low current), two, three or more test plugs 106 can be provided.

The exchangeable connector 108 is configured to be exchangeably assembled with the casing 102 and comprises a number of second interface members 110 (corresponding to the number of first interface members 104, in the shown embodiment four) being electrically couplable to the device under test 150 when located at the device under test receptacle 112 of the connector 108. The number of first interface members 104 and the number of second interface members 110 is usually the same with a one-to-one assignment of a respective first interface member 104 and a corresponding second interface number 110.

The first interface members 104 and the second interface members 110 are configured for establishing an electrically conductive connection from the device under test receptacle 112 to the test plug 106 upon assembling the connector 108 with the casing 102. In other words, by the mechanical assembly procedure between casing 102 and connector 108, simultaneously a high current compatible electric connection between the interface members 104, 110 is established in a single procedure.

The casing 102 and the connector 108 are configured for being assembled by attaching the connector 108 from a bottom side to the casing 102 and subsequently actuating a lever-based actuating mechanism 114 of the casing 102 to thereby lock the connector 108 to the casing 102 (see FIG. 4 and FIG. 5). By this procedure, an electrically conductive connection between the first interface members 104 and the second interface members 110 is established simultaneously, i.e. this procedure also brings the interface members 104, 110 into electrically conductive engagement.

The lever-based actuating mechanism 114, which is best seen in FIG. 3A, FIG. 3B, FIG. 4 and FIG. 5, comprises a lever 116 being pivotable manually by a user for converting the measuring device 100 between a locked or assembled state between casing 102 and connector 108 (see FIG. 4), and a separated or disassembled state between casing 102 and connector 108 (see FIG. 5). Further components of the actuating mechanism 114 are a slanted element 118 such as a wedge shaped body, and a motion conversion mechanism 120 for converting a pivoting motion of the lever 116 into a longitudinal motion of the slanted element 118. The motion conversion mechanism 120 comprises a coupling rod 160 being rigidly connected to the lever 116 and having a circumferentially toothed end 162. When the lever 116 pivots, the coupling rod 160 rotates together with its toothed end 162. The teeth of the rotating toothed end 162, in turn, engage teeth of a pinion 164. Thus, pinion 164 together with the slanted element 118 move longitudinally. As a consequence, respective protrusions 122 (such as ball bearings) of the connector 108, best seen in FIG. 2, move along assigned slanted element 118 and thereby spatially approaches the connector 108 to the casing 102 in accordance with a follower principle. This can be also seen in FIG. 3A where an approximate position of the protrusion 122 is indicated schematically with reference numeral 122′, and where the longitudinal motion of a coupling body 302 connecting the slanted element 118 with the pinion 164 is indicated with a double arrow 300. Thus, the respective protrusion 122 is configured for being movable by actuating the actuating mechanism 114 to thereby assemble the connector 108 to the casing 102. In a nutshell, pivoting the lever 116 results in an elevation of the connector 108 towards the casing 102 and thereby forces the interface members 104, 110 into engagement with one another for establishing an electric connection.

In addition, the actuating mechanism 114 is configured so that, in a position of the actuating mechanism 114 after having assembled the casing 102 and the connector 108, an actuation disabling element 176 disables further actuation of the actuating mechanism 114 unless the actuation disabling element 176 is actively disabled by a user. Thus, when the measuring device 100 is in the not connected condition between casing 102 and connector 108 as shown in FIG. 5, the user may freely activate the lever 116 to convert the measuring device 100 into the connected condition between casing 102 and connector 108 as shown in FIG. 4 without the need to overcome the actuation disabling element 176. Thus, the assembly procedure is very intuitive for a user. When however the measuring device 100 is in the connected or locked condition as shown in FIG. 4, the actuation disabling element 176 acts as a safety mechanism against undesired disassembly of the measuring device 100, which might be dangerous for example during a test. Therefore, for converting the measuring device 100 from the state shown in FIG. 4 into the state shown in FIG. 5, the user first has to overcome the protection mechanism provided by the actuation disabling element 176 before being able to separate casing 102 and connector 108 from one another (for instance to substitute the connector 108 by another connector 108 to readjust the measuring device 100 for a subsequent other test).

Thus, the connector 108 is in a position being locked to the casing 102 in FIG. 4 and is in a position being unlocked with regard to the casing 102 in FIG. 5. For mounting a connector 108 to the casing 102, the casing 102 is positioned upside down or is rotated by 180°, as shown in FIG. 4 and FIG. 5. Then, the desired connector 108 is inserted into an insertion recess of the casing 102. In this condition, the pogopins are in a loose, unbiased state. Subsequently, the lever 116 is pivoted by 180° so that the protrusion 122 is moved along the slanted element 118, thereby completing the coupling procedure by locking the connector 108 to the casing 102.

By the assembly procedure described above for the casing 102 and the connector 108, an uninterrupted electrically conductive coupling path from one or more terminals of the device under test 150 arranged at the device under test receptacle 112 of the connector 108, via one or more terminals at the device under test receptacle 112, via one or more electric coupling elements 126 (such as cables connected by soldering) between the device under test receptacle 112 and the second interface members 110, from the second interface members 110 to the first interface members 104, and via one or more further electric coupling elements 166 (such as cables connected by soldering) between the first interface members 104 into the one or more test plugs 106. Thus, electric coupling elements 126, 166, which may be embodied as electric connection cables, may be provided for electrically coupling the first interface members 104 with the test plugs 106 and electrically coupling the second interface members 110 with the receptacles 112.

As best seen in FIG. 2, the connector 108 may be based on a planar support plate 170 which, for instance, may be made from a fabric-based plastic (such as a mixture of resin and glass fibers) and may be capable to withstand high temperatures of for example up to 150° C. and/or high current values of for example up to 10 Ampere. A plurality of through holes 172 may be formed in the support plate 170. Moreover, a plurality of mounting structures 174 may be formed on and extending vertically beyond the support plate 170, wherein each of the mounting structures 174 may be configured for carrying a respective one of the second interface members 110 at an exposed position, thereby promoting the connectability with the respective first interface number 104.

Again referring to FIG. 2, a type plate 190 may be screwed to the support plate 170. Furthermore, reference numeral 192 indicates the presence of 20 terminals capable for a high current connection, and reference numeral 196 indicates the presence of 85 terminals capable for a high current connection. Reference numeral 194 shows the individually wiring of the respective second interface members 110 to pogopins contacting the device under test 150 during a test. Reference numeral 122 shows the four protrusions (only two being visible in FIG. 2), embodied as ball bearings, used for elevating and locking the connector 108 to the casing 102 as accomplished by the lever mechanism 114.

Again referring to FIG. 3A, the lever 116 is shown in a closed position corresponding to FIG. 4. It can be converted into an open position by pivoting it by 180°.

Again referring to FIG. 3B, reference numeral 302 indicates the presence of 2×20 terminals capable for a high current connection, and reference numeral 304 indicates the presence of 2×85 terminals capable for a high current connection. As indicated by reference numeral 306, a connector identification unit is provided which is capable of automatically identifying a respective connector 108 when being coupled to the casing 102.

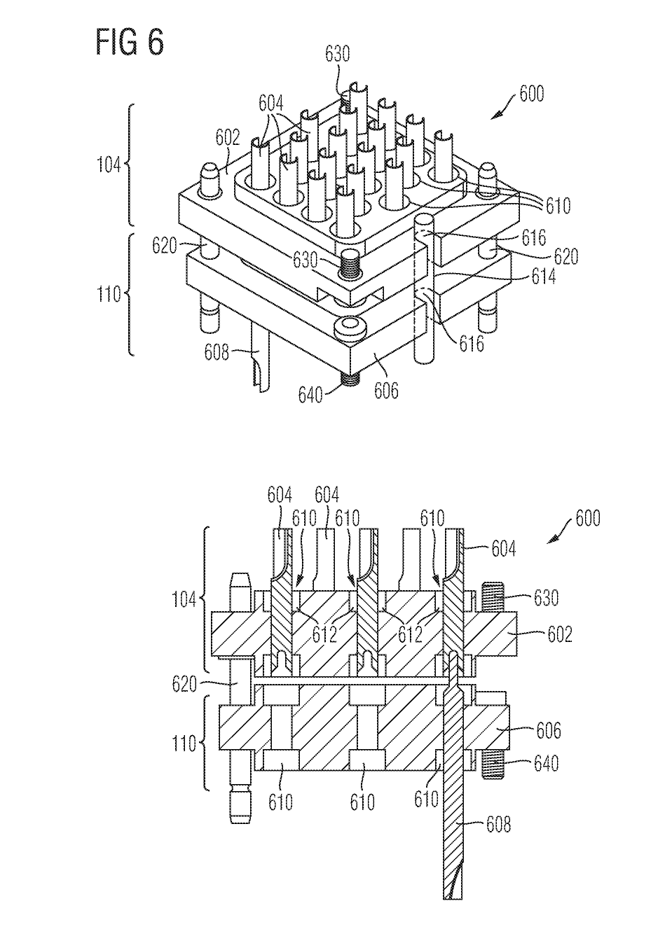

FIG. 6 to FIG. 8 each shows a three-dimensional view and a cross-sectional view of a respective interface assembly 600 each composed of mutually cooperating reversibly attachable or detachable interface members 104, 110 according to exemplary embodiments of the invention.

The interface assembly 600 according to FIG. 6 comprises first interface member 104 (which may form part of casing 102) which is formed, in turn, of an electrically insulating first carrier structure 602 and a plurality of electrically conductive first pins 604 extending through part of the first carrier structure 602 and being arranged in a matrix pattern, i.e. in rows and columns. Moreover, the interface assembly 600 comprises second interface member 110 (which may form part of connector 108, to be assembled with the casing 102) which, in turn, comprises an electrically insulating second carrier structure 606 and one or more electrically conductive second pins 608 extending through the entire second carrier structure 606. The first interface member 104 and the second interface member 110 are configured for establishing an electrically conductive connection between one of the first pins 604 and the second pin 608 upon assembling the connector 108 with the casing 102. FIG. 6 shows a configuration in which this electric coupling is established, see right hand side of the lower part of FIG. 6.

The first interface member 104 and the second interface member 110 are configured to withstand application of high current electric test signals (for instance a current of several Ampere at a voltage of several kilovolt) under high temperature conditions (for instance up to 150° C.). The first carrier structure 602 and the second carrier structure 606 are both formed of a fabric-based plastics comprising fibers embedded in a resin matrix and being capable to withstand 150° C. and a current of several Ampere without deterioration.

As can be taken from FIG. 6, both the first interface member 104 and the second interface member 110 is equipped with a creep current path length extension feature 610 embodied as a plurality of cup shaped recesses 612 in both opposing main surface portions of both the first carrier structure 602 and the second carrier structure 606. Hence, when the first pins 604 and the second pin 608 are embedded in the first carrier structure 602 and the second carrier structure 606, respectively, the cup shaped recesses 612 circumferentially space the respective carrier structure 602, 606 with regard to the respective pin 604, 608. This can be seen best in the lower image of FIG. 6. When an undesired creep current tends to flow for example from one of the first pins 604 to another one of the first pins 604 along a surface of the first dialectic carrier 602, the presence of the cup shaped recesses 612 significantly increases the length of the flow path along which a creep current has to flow for unintentionally short circuiting different ones of the first pins 604.

The upper image in FIG. 6 schematically shows a positioning bolt 614 which is configured for engaging in corresponding positioning recesses 616 of each of the first interface member 104 and the second interface member 110 so that assembly of the first interface member 104 and the second interface member 110 is only enabled in positions in which the positioning bolt 614 extends into both positioning recesses 616. Thus, the presence of the positioning bolt 614 makes it mechanically impossible to erroneously assemble the interface members 104, 110. In a scenario in which a user erroneously mounts the second interface member 610 on a mounting base 174 (for instance rotated by 180° as compared to the correct mounting position) the positioning bolt 614 prevents assembly of the interface members 104, 110 in the incorrect position. Only when the mutual position is correct, see FIG. 6, and the positioning recesses 616 are in alignment or in flush with one another, the positioning bolt 614 is capable of extending through both of these positioning recesses 616.

Moreover, bearing bolts 620 are provided which function for fixing, with a certain clearance, the interface members 104, 110. While the interface members 104, 110 are allowed for carrying out a certain equilibration motion in the plane perpendicular to the bearing bolts 620, the bearing bolts 620 limit this balancing motion to thereby center the interface members 104, 110.

Furthermore, a first mounting element 630 allows to mount (for instance by screwing) the first interface member 104 to the casing 102, and a second mounting element 640 allows to mount (for instance by screwing) the second interface number 110 to the connector 108.

FIG. 6 shows interface members 104, 110 configured for carrying out a static high current test. The number of possible connections is 18, the maximum voltage is 2.5 kV, the maximum current is 24 Ampere, the maximum temperature is 150° C., the stroke width (for establishing the connection) is 4 mm, and the contact force at this stroke width is 2.25 Newton per pin. The casing side (i.e. the first pins 604 in the first carrier structure 602 of the first interface member 104) has a floating bearing, whereas the connector side (i.e. the second carrier structure 606 of the second interface member 110) has a fixed bearing.

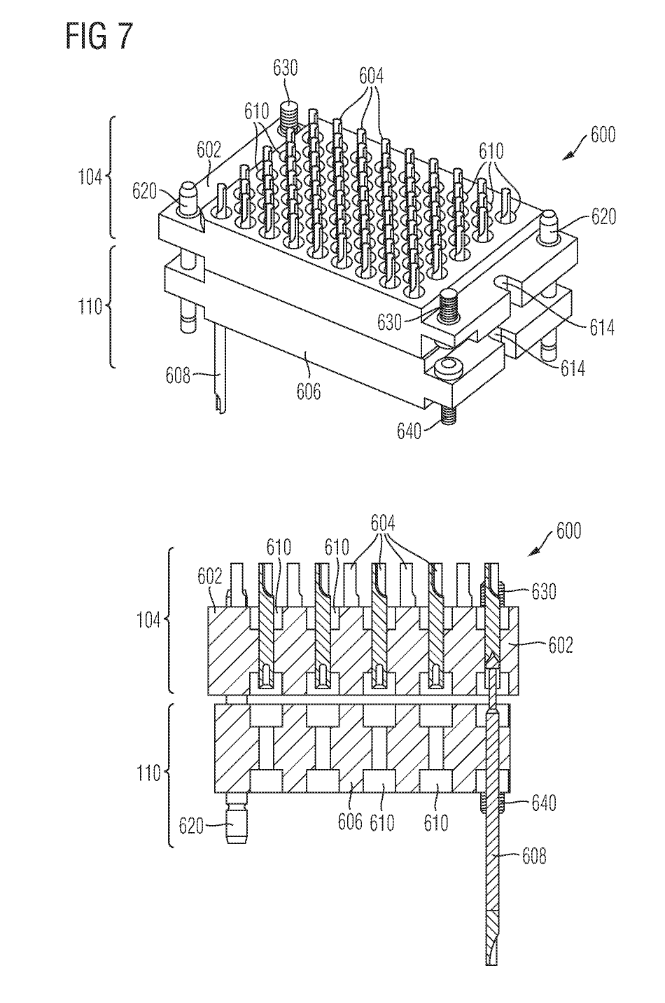

The embodiment of FIG. 7 differs from the embodiment according to FIG. 6 in particular in that, according to FIG. 7, interface members 104, 110 are configured for carrying out a static low current test. According to FIG. 7, the number of possible connections is 85, the maximum voltage is 2.5 kV, the maximum current is 4 Ampere, the maximum temperature is 150° C., the stroke width (for establishing the connection) is 4 mm, and the contact force at this stroke width is 2.25 Newton per pin. The casing or adapter side has a floating bearing, whereas the connector side has a fixed bearing.

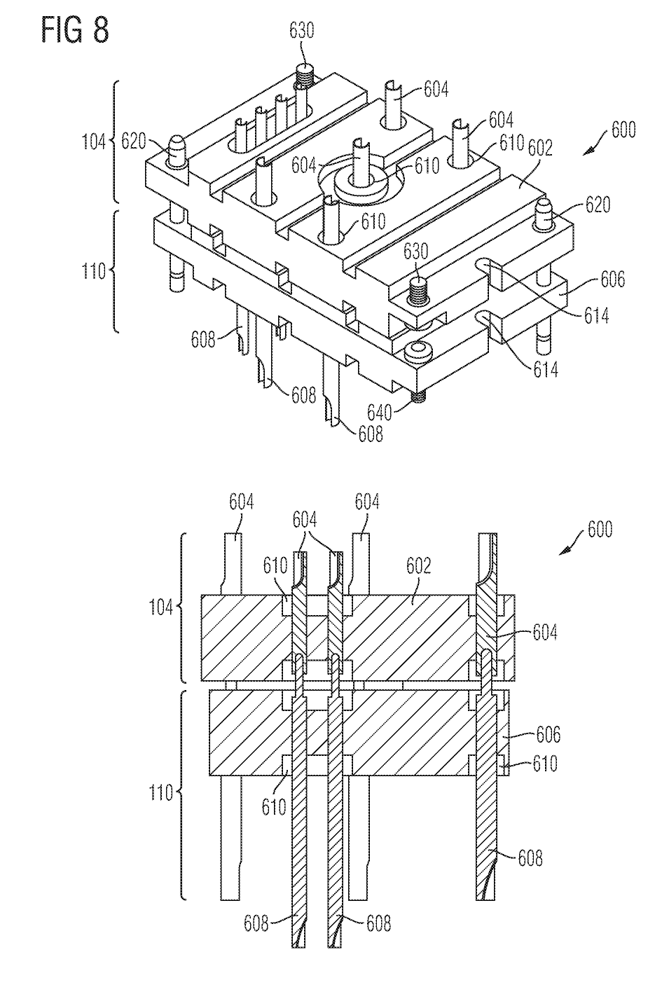

The embodiment of FIG. 8 differs from the embodiment according to FIG. 6 in particular in that, according to FIG. 8, interface members 104, 110 are configured for carrying out a high current Iso test (isolation test). According to FIG. 8, the number of possible connections is 5 or 4, the maximum voltage is 6 kV or 0.5 kV, the maximum current is 24 Ampere or 4 Ampere, the maximum temperature is 150° C., the stroke width (for establishing the connection) is 4 mm, and the contact force at this stroke width is 2.25 Newton per pin. The casing or adapter side has a floating bearing, whereas the connector side has a fixed bearing.

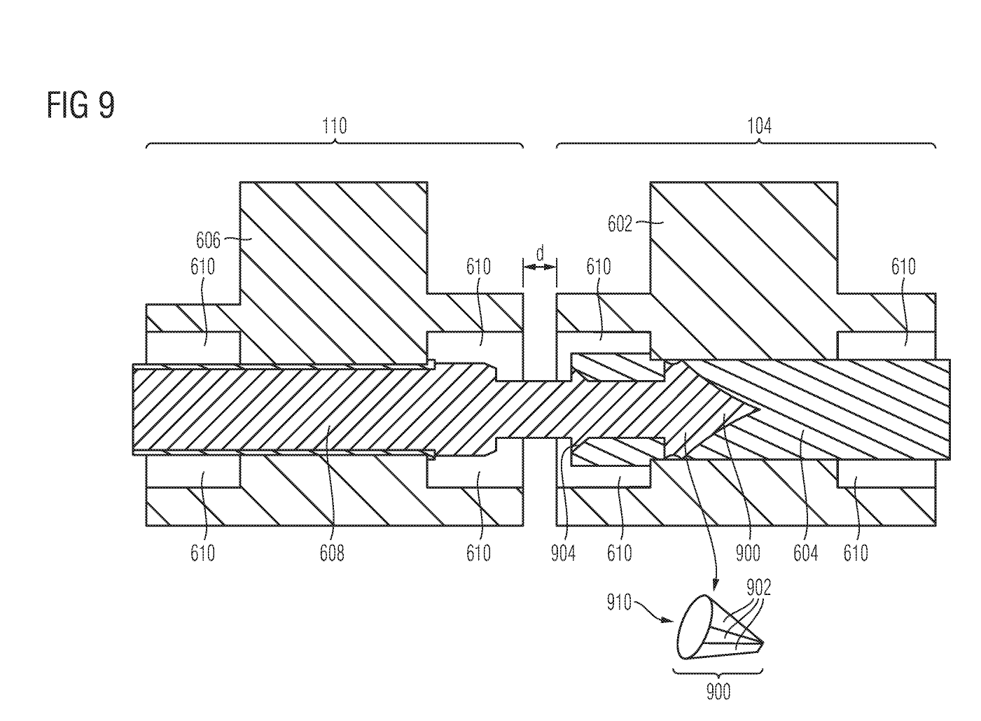

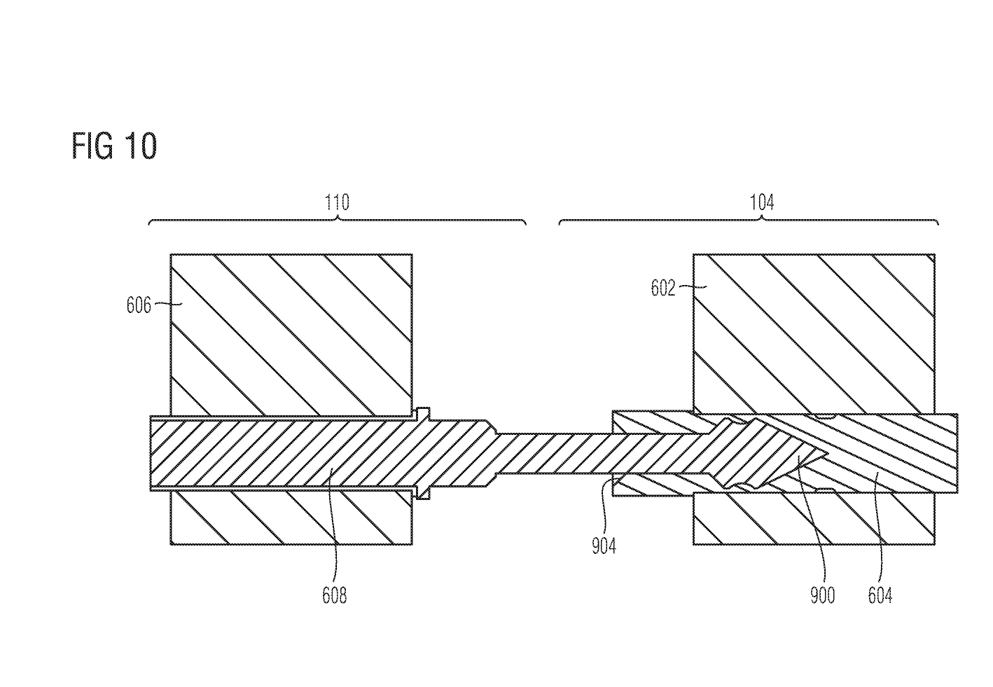

FIG. 9 shows a detailed view of the interface assembly 600 of the two interface members 104, 110 according to any of FIG. 6 to FIG. 8 in an assembled state. FIG. 10 shows the interface assembly 600 of FIG. 9 in a non-assembled state, i.e. with a larger distance between the carrier structures 602, 606. The second pins 608, which can be pogopins, comprise an elastic bearing embodied as a spring-based bearing and are therefore configured for enabling an axial balancing motion. This allows for an equilibration motion of the interface assembly 600 in the axial direction (corresponding to the horizontal direction according to FIG. 9) of the pins 604, 608. Moreover, the first pins 604 embedded in the first carrier structure 602 comprise a floating bearing configured for enabling a radial balancing motion. This allows for an equilibration motion of the interface assembly 600 in a radial plane (perpendicular to the horizontal direction according to FIG. 9) of the pins 604, 608. The enablement of a limited equilibration in each direction prevents high mechanical load and therefore the danger of breakage of the interface assembly 600 in the event of a small spatial mismatch during assembly. In contrast to the second pins 608 in the second carrier structures 606, the first pins 604 in the first carrier structures 602 are fixedly supported in an axial direction without being enabled to carry out an equilibration motion in the axial direction. In contrast to the first pins 604 in the first carrier structures 602, the second pins 608 in the second carrier structures 606 are fixedly supported in a radial plane without being enabled to carry out an equilibration motion in the radial plane.

As can be taken from FIG. 9 and in particular a detail 910 shown there, the second pins 608 comprise a tapering end 900 having multiple separate contact surfaces 902, configured for reversibly engaging in a sleeve shaped end 904 of a respective one of the first pins 604. Thus, the contact area between the male type second pins 608 and the female type first pins 604 (having a sleeve like connection portion) can be made large, thereby ensuring a proper electric contacting.

As can be taken from FIG. 9, the first interface member 104 and the second interface member 110 are configured to maintain spaced by a predefined distance, d, between the first carrier structure 602 and the second carrier structure 606 upon assembling the connector 108 with the casing 102. This promotes proper electric isolation between the respective pins 604, 608 and suppresses creep current. In the disassembled state of FIG. 10, a distance between the first carrier structure 602 and the second carrier structure 606 is larger than d.

FIG. 11A and FIG. 11B show illustrations of a test arrangement 1180 according to an exemplary embodiment of the invention.

The test arrangement 1180 is configured for testing a device under test 150. The test arrangement 1180 comprises measuring device 100 for accommodating and electrically contacting the device under test 150 and a test apparatus 1150 on which the measuring device 100 is mounted. The test apparatus 1150 serves as a mounting base for the measuring device 100 which is attached on top of the test apparatus 1150. Beforehand, an appropriate exchangeable connector 108 (selected in accordance with the type of test to be executed and/or the type of DUT to be tested) has already been mounted on the bottom of the casing 102 in the way as described above referring to FIG. 1 to FIG. 5. After the test has started, the test apparatus 1150 supplies or feeds a device under test 150 to be tested to the device under test receptacle 112 of the connector 108 and electrically contacts terminals thereof. For example, a device under test 150 may be transported from a DUT container (not shown) via a movable carrier table 1160 (using a suction process) to the device under test receptacle 112. In other words, the movable carrier 1160 carrying the device under test 150 may move to a bottom of the measuring device 100 so as to bring the device under test 150 in functional interaction with the device under test receptacle 112. Then, the test apparatus 1150 applies test signals in accordance with a predefined test protocol to the respective test plug(s) 106 from where the electric signals are conducted to the contacted terminals the device on the test 150. In response to the application of these test signals, the device under test 150 generates corresponding response signals which are, in turn, conducted from the device under test 150 via the measuring device 100 towards the test plug(s) 106 and from there to the test apparatus 1150 for signal processing. The movable carrier 1160 may then move back so as to remove the device under test 150 from the functional interaction with the measuring device 100. Depending on the response signal, the test apparatus 1150 may then decide whether the device under test 150 has passed the test or has failed the test. It is also possible that the result of the test is that the test apparatus 1150 conveys the device under test 150 back to a manufacturing line for post processing or decides that further tests have to be carried out with the device under test 150.

Although not shown in FIG. 11A and FIG. 11B, the test apparatus 1150 and/or the measuring device 100 may be configured for heating the device under test 150 to an elevated temperature (for instance at least up to 80° C., in particular up to 150° C.) compared to ambient temperature (for instance 20° C.) during the test. For this purpose, a correspondingly controllable temperature adjustment unit (not shown, for instance comprising a heater) may be provided.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A measuring device for accommodating and electrically contacting a device under test to be tested in cooperation with a test apparatus, the measuring device comprising:
a casing comprising a first interface member being electrically couplable to the test apparatus when the test apparatus is connected to a test plug of the casing;
an exchangeable connector configured to be exchangeably assembled with the casing and comprising a second interface member being electrically couplable to a device under test when located at a device under test receptacle of the connector;
wherein the first interface member and the second interface member are configured for establishing an electrically conductive connection from the device under test receptacle to the test plug upon assembling the connector with the casing.

2. The measuring device according to claim 1, wherein the casing and the connector are configured for being assembled by attaching the connector to the casing and actuating an actuating mechanism of the casing which simultaneously establishes the electrically conductive connection between the first interface member and the second interface member.

3. The measuring device according to claim 2,
wherein the actuating mechanism comprises a lever pivotable by a user, a slanted element, and a motion conversion mechanism for converting a pivoting motion of the lever into a longitudinal motion of the slanted element;
wherein the connector comprises a protrusion configured for moving along the slanted element to thereby lock the connector to the casing upon pivoting the lever.

4. The measuring device according to claim 2, wherein the actuating mechanism is configured for establishing the electrically conductive connection between the first interface member and the second interface number by approaching the connector towards the casing upon actuation.

5. The measuring device according to claim 2, wherein the actuating mechanism is configured so that, in a position of the actuating mechanism after having assembled the casing and the connector, an actuation disabling element disables further actuation of the actuating mechanism unless the actuation disabling element is disabled by a user.

6. The measuring device according to claim 1, comprising a plurality of first interface members and a plurality of second interface members, wherein respective pairs of one of the first interface members and one of the second interface members are configured for pairwise interacting for establishing the electrically conductive connection from the receptacle to the test plug.

7. The measuring device according to claim 1, comprising at least one further exchangeable connector, wherein each of the plurality of connectors is configured to be exchangeably assembled with the casing and each configured for being electrically couplable to a different type of a device under test.

8. The measuring device according to claim 1, further comprising:
at least one further casing, wherein each of the plurality of casings is configured for supporting a respective one of different types of tests of a device under test;
at least one further exchangeable connector, wherein each of the plurality of connectors is configured for supporting a respective one of the different types of tests of a device under test, is configured to be exchangeably assembled with a respective one of the casings, and is configured for being electrically couplable to a device under test being subject to testing in accordance with the respective one of different types of tests supported by the respective connector and the respective casing when a device under test is located at a device under test receptacle of the respective connector.

9. A measuring device for accommodating and electrically contacting a device under test to be tested in cooperation with a test apparatus, the measuring device comprising:
a casing;
a plurality of exchangeable connectors each configured to be exchangeably assembled with the casing and each configured for being electrically couplable to a different type of a device under test.

10. A test arrangement for testing a device under test, the test arrangement comprising:
a measuring device according to claim 1 for accommodating and electrically contacting a device under test to be tested;
a test apparatus with which the measuring device is assemblable or assembled, being configured for supplying the device under test to the connector, for applying a test signal via the casing to the device under test, and for receiving a response signal to the test signal from the device under test via the casing.

11. An interface assembly for a measuring device for accommodating and electrically contacting a device under test to be tested in cooperation with a test apparatus, the interface assembly comprising:
a first interface member for a casing of the measuring device and comprising an electrically insulating first carrier structure and one or a plurality of electrically conductive first pins extending through at least a part of the first carrier structure;
a second interface member for a connector, to be assembled with the casing, of the measuring device and comprising an electrically insulating second carrier structure and one or a plurality of electrically conductive second pins extending through at least a part of the second carrier structure;
wherein the first interface member and the second interface member are configured for establishing an electrically conductive connection between the one or more first pins and the one or more second pins upon assembling the connector with the casing;
wherein at least one of the first interface member and the second interface member is configured to withstand application of a high current electric test signal under high temperature conditions.

12. The interface assembly according to claim 11, wherein at least one of the first carrier structure and the second carrier structure comprises or consists of a fabric-based plastics, in particular fibers embedded in a resin matrix.

13. The interface assembly according to claim 11, wherein at least one of the first interface member and the second interface member is equipped with a creep current path length extension feature.

14. The interface assembly according to claim 13, wherein the creep current path length extension feature is formed as at least one cup shaped recess in at least one main surface portion of at least one of the first carrier structure and the second carrier structure so that, when a respective one of the one or more first pins and the one or more second pins is embedded in a respective one of the first carrier structure and the second carrier structure, the cup shaped recess circumferentially spaces the respective carrier structure with regard to the respective pin.

15. The interface assembly according to claim 11, wherein the one or more second pins comprise an elastic bearing, in particular a spring-based bearing, configured for enabling an axial balancing motion.

16. The interface assembly according to claim 11, wherein the one or more first pins in the first carrier structure comprise a floating bearing configured for enabling a radial balancing motion.

17. The interface assembly according to claim 11, wherein the one or more second pins comprise a tapering end, in particular a tapering end having multiple separate contact surfaces, configured for reversibly engaging in a sleeve shaped end of a respective one of the one or more first pins.

18. The interface assembly according to claim 11, wherein the first interface member and the second interface member are configured to remain spaced by a predefined distance between the first carrier structure and the second carrier structure in an assembled state between the connector and the casing.

19. A method of using a measuring device according to claim 1, an interface assembly according to claim 11, or a test arrangement according to claim 10, wherein the method comprises testing a power package as device under test, in particular a power package comprising at least one power semiconductor chip.

20. A method of using a measuring device according to claim 1, an interface assembly according to claim 11, or a test arrangement according to claim 10, wherein the method comprises testing a device under test involving at least one of applying a high current electric test signal, in particular with a current of at least 4 Ampere, to the device under test, and heating the device under test to a temperature above ambient temperature, in particular to a temperature above 100° C.
